(19) United States
(12) Patent Application Publication
(10) Pub. No.: US 2026/0060006 A1
(43) Pub. Date: Feb. 26, 2026

(54) TUNING SPIN QUBITS HAVING ANISOTROPIC G-TENSORS

(71) Applicant: INTERNATIONAL BUSINESS MACHINES CORPORATION, ARMONK, NY (US)

(72) Inventors: Gian R. von Salis, Aeugst am Albis (CH); Michele Aldeghi, Cadro (CH); Konstantinos Tsoukalas, Zurich (CH); Andreas Fuhrer Janett, Zurich (CH)

(21) Appl. No.: 18/811,723

(22) Filed: Aug. 21, 2024

(51) Int. Cl. H10N 50/20; G06N 10/70

(52) U.S. Cl. CPC H10N 50/20; G06N 10/70

(57) ABSTRACT

A quantum computing system is configured to perform a method that applies a baseline gate voltage to a quantum gate that forms a hole spin quantum dot (qubit). The baseline gate voltage is incremented until reaching a tuning voltage that displaces the qubit relative to a nonhomogeneous field producing element enough to orient a Larmor vector of the qubit in a predetermined direction.

### STATEMENT REGARDING FEDERALLY SPONSORED RESEARCH OR DEVELOPMENT

This application was made with government support under project NCCR SPIN, grant number is 51NF40_180604, awarded by the Swiss National Science Foundation.

### BACKGROUND

### Technical Field

The present disclosure generally relates to spin quantum computing with an array of quantum dots (qubits) in a magnetic field, and more particularly but not by way of limitation, to tuning the magnetic field individually for each qubit in the array for improved signal fidelity in quantum gate operations.

### Description of the Related Art

Quantum computation studies the application of quantum phenomena for information processing and communication. Various models of quantum computation exist, and some popular models include the concepts of qubits and quantum gates. A qubit is a generalization by a wavefunction that has two possible states but can be in a quantum superposition of both states. A quantum gate is a generalization of a classical logic gate. However, the quantum gate describes the transformation that one or more qubits will experience after one or more control parameters are changed for a certain time. Specifically for the type of spin qubits considered here, such control parameters may consist of voltages that are applied to electric gates that control the electric environment of the holes confined in the quantum dots. Various quantum phenomena, such as superposition and entanglement, do not have analogs in the world of classical computing and therefore may involve special structures, techniques, temperature environments, and materials.

### SUMMARY

According to one embodiment, an apparatus is provided that has a semiconductor substrate. A plurality of quantum gates on the semiconductor substrate form an array of hole spin quantum dots (qubits) at respective qubit positions in a qubit plane on the semiconductor substrate. A magnetic field producing element is configured to produce a total magnetic field. The magnetic field producing element includes a homogeneous field producing element configured to produce a homogenous magnetic field acting collectively on all the qubits in the array in a direction parallel to the qubit plane. The magnetic field producing element also includes a nonhomogeneous field producing element configured to produce a nonhomogeneous magnetic field acting individually on each qubit in the array. Tuning circuitry is configured to optimize signal fidelity of the plurality of quantum gates by individually tuning each qubit to the total magnetic field.

According to one embodiment, a method is provided for qubit tuning to optimize signal fidelity of quantum gates in a qubit computing system. The method includes applying a baseline voltage to a selected one of a plurality of quantum gates that each define an electrostatic potential of a quantum dot in which a hole spin is confined. The baseline voltage is incremented by an additional voltage until reaching a tuning voltage that displaces the selected hole spin relative to a nonhomogeneous magnetic field producing element. The displacement orients a Larmor vector of the selected quantum dot substantially parallel to a predetermined direction.

According to one embodiment, a quantum computing system is configured to perform a method that applies a baseline gate voltage to a quantum gate that forms a hole spin quantum dot (qubit). The baseline gate voltage is incremented until reaching a tuning voltage that displaces the qubit relative to a nonhomogeneous field producing element configured to orient a Larmor vector of the qubit substantially parallel to a total magnetic field.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 illustrates a quantum computing system having a one-dimensional array of hole spin quantum dots (qubits) on a semiconductor substrate, consistent with illustrative embodiments.

FIG. 2a depicts one of the qubits in FIG. 1 at an initial position, consistent with illustrative embodiments.

FIG. 2b depicts the qubit in FIG. 2a after it has been displaced by application of a displacement gate voltage V_{d1}, consistent with illustrative embodiments.

FIG. 3 illustrates spin precession around a magnetic field, consistent with illustrative embodiments.

FIG. 4 illustrates the anisotropic g-tensor of the qubit in FIG. 1 at a cross-section along the x-y plane, consistent with illustrative embodiments.

FIG. 5a depicts three qubits at different respective initial positions, consistent with illustrative embodiments.

FIG. 5b is similar to FIG. 5a but after gate voltages V_{d1}, V_{d3} are applied to displace qubits 1101, 1103 relative to respective portions of the nonhomogeneous field B_{N1}, B_{N3}, consistent with illustrative embodiments.

FIG. 6 is a flowchart depicting a method for g-tensor tuning to optimize signal fidelity of quantum gates in a qubit computing system, consistent with illustrative embodiments.

FIG. 7 depicts the nonhomogeneous field formed by a two-piece magnetic structure, consistent with illustrative embodiments.

FIG. 8 depicts the nonhomogeneous field formed by a magnetic structure having a pair of poles and a joint that joins the pair of poles together, consistent with illustrative embodiments.

FIG. 9 depicts a one-dimensional qubit array that includes the magnetic members in FIG. 7, consistent with illustrative embodiments.

FIG. 10 depicts a two-dimensional qubit array that includes the magnetic members in FIG. 7, consistent with illustrative embodiments.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

Although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It is to be understood that other embodiments can be used, and structural or logical changes can be made, without departing from the spirit and scope defined by the claims. The description of the embodiments is not limiting. In particular, elements of the embodiments described hereinafter may be combined with elements of different embodiments.

Various aspects of the present disclosure are described by narrative text, flowcharts, block diagrams of computer systems and/or block diagrams of machine logic. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

It has been found that to increase the reliability of a quantum computing system, improvements can be made to reduce the error rates, which is relevant to manipulating qubit states accurately. In one aspect, the teachings herein are based on insight that the signal fidelity of quantum gate operations on a hole spin qubit can be related to its g-tensor main axis orientation with respect to the magnetic field direction. But the orientations of g-tensors can vary depending on manufacturing variations such as strain, imperfections, misalignments, and the like. Therefore, gate fidelities cannot be maximized simultaneously for all qubits in a global magnetic field. Furthermore, embodiments of the present disclosure are further based on recognition that issues unique to quantum circuits have been taken into consideration when evaluating applicability of classical signal processing techniques, and in particular, to selecting structures and methods used for interacting efficiently with qubits.

In this detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the drawing figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip. As used herein, the term “vertical” describes an orientation that is arranged perpendicular to the first surface of a chip, chip carrier, or semiconductor body. As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments can be used, and structural or logical changes can be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

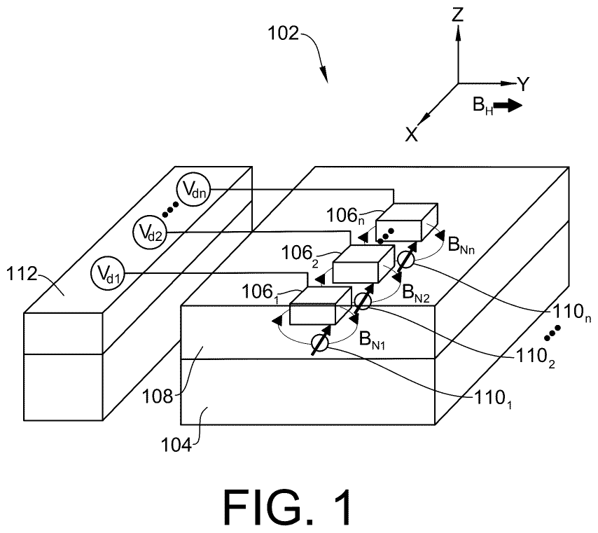

FIG. 1 illustrates a complementary metal oxide semiconductor (CMOS) integrated circuit forming a qubit computing system 102 on a support substrate 104. The support substrate 104 can be made of any suitable substrate material, such as, for example, monocrystalline Si, silicon germanium (SiGe), III-V compound semiconductor, II-VI compound semiconductor, or semiconductor-on-insulator (SOI).

In this example, the qubit computing system 102 has a plurality of quantum gates 106 on a semiconductor substrate 108, such as a FinFET or nanowire and the like, forming an array of hole spin quantum dots (qubits) 110. The qubits 110 can be arranged in a qubit plane on the semiconductor substrate 108. In this example, the qubit plane is parallel to the xy coordinate plane. The gates 106 can be plunger gates that are used to form the qubits 110, and to control the electrical potentials of individual qubits 110. Barrier gates (not shown) can be placed in spaces between the qubits 110. The barrier gates can be used to control tunneling and thereby control exchange interactions between adjacent qubits 110.

The qubits 110 are influenced by a magnetic field producing element configured to produce a total magnetic field. The magnetic field producing element can have a homogeneous field producing element configured to produce a homogenous magnetic field B_{H}. The magnetic field producing element can also have a nonhomogeneous field producing element configured to produce a nonhomogenous magnetic field B_{N}. B_{H} acts collectively on all the qubits 110 in a direction that is parallel to the xy coordinate plane, and thus parallel to the qubit plane. B_{N} acts individually on each qubit 110 in directions that are both parallel and antiparallel to the qubit plane. In this illustrative example, peripheral tuning circuitry 112 can be configured to optimize signal fidelity of the quantum gates by individually tuning the magnetic field for each qubit 110.

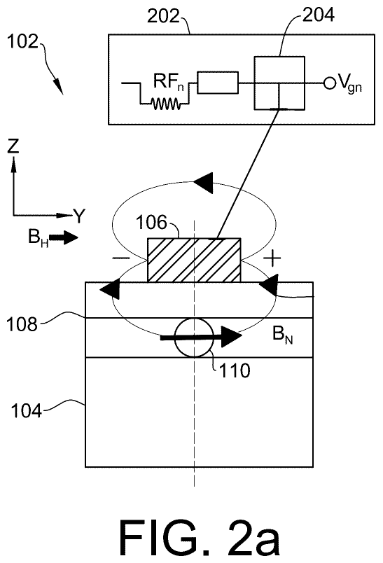

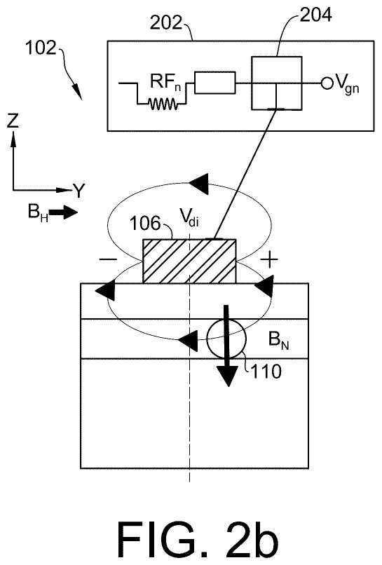

FIGS. 2a and 2b illustrate a way of manipulating the spin state by individually tuning the magnetic field for each qubit 110, consistent with illustrative embodiments. These FIGS. illustrate the quantum computing system 102 can include multi-step and layered sequences of, for example, photolithographic and/or chemical processing steps that facilitate gradual creation of electronic-based systems, devices, components, and/or circuits in a semiconducting and/or a superconducting device (such as an integrated circuit). For instance, quantum computing system 102 can be fabricated by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

FIG. 2a illustrates the gate 106 can be a deposited and etched layer on the semiconductor substrate 108. The semiconductor substrate 108 can be formed of silicon, while it will be understood that other materials can be used as well, including, without limitation, silicon dioxide, aluminum oxide, sapphire, germanium, gallium arsenide (GaAs), an alloy of silicon and germanium, or indium phosphide (InP). Accordingly, as used herein, the term substrate includes all forms of semiconductor structures. The term “semiconductor” as used herein denotes any semiconducting material including, for example, Si, Ge, SiGe, SiC, SiGeC, and III-V compound semiconductors such as InAs, GaAs and InP. Generally, the semiconductor substrate 108 can be formed of any suitable chip/wafer material (such as a silicon substrate), and be any suitable size, shape, and/or dimensions.

The gate 106 can be specially configured as a magnetic structure that is such that it is generally parallel to B_{H}. One way can be to deposit the gate 106 as a gate layer on the semiconductor substrate 108, such as by physical vapor deposition (PVD), chemical vapor deposition (CVD), and plasma enhanced CVD (PECVD). In other examples the gate layer can be deposited by metal-organic chemical vapor deposition (MOCVD), atomic layer deposition (ALD), plasma enhanced ALD (PEALD), low pressure CVD (LPCVD), and combinations thereof. The magnetic gate 106 can have multiple magnetic and otherwise conductive layers of different metals and/or metal compounds. In this way, the magnetic structure can be located about 500 nanometers or less from the qubit 110.

The qubit 110 in FIG. 2a is at an initial (or equilibrium) position that is aligned with the center of the source of the stray magnetic field B_{N}. This alignment means there would be no upward or downward component of B_{N} acting on the qubit 110 at the initial position. But displacing the qubit 110 relative to B_{N}, as shown in FIG. 2b, subjects the qubit 110 to the downward component of B_{N} on the right side of the qubit 110. Likewise, displacing the qubit to the left will subject the qubit 110 to the upward component of B_{N}.

For a single hole wavefunction in a quantum dot, the hole wavefunction can be shifted spatially by electric fields. For example, the hole wavefunction for the qubit 110 can be controlled by varying the gate voltage V_{d} on the gate 106 to spatially displace the qubit 110 away from its initial position. Programmed tuning circuitry 202 can include a bias 204 controlling applications of analog radio-frequency (RF) signals and digital gate voltage signals.

FIG. 2b is similar to FIG. 2a but depicting voltage V_{d1} has been applied to the gate 106 to displace the qubit 110 from its initial position in FIG. 2a. This results in increasing the vertical component of B_{N} at the hole spin location. This small out-of-plane change in B_{N} (such as on the order of +5 mT) is amplified by the qubit's anisotropic g-tensor in the total magnetic field, such as on the order of resulting in a 500 mT increase. This causes a large rotation of the Larmor vector flipping its basis, such as vertically.

In this manner, B_{N} can include an arcuate stray magnetic field extending from one end of the (magnetic) gate 106 to an opposing end of the gate 106. The stray magnetic field forms stray magnetic field components acting upwardly, or in directions toward the gate 106, on the left side of the qubit 110. Similarly, the stray magnetic field forms stray magnetic field components acting downwardly, or in directions away from the gate 106, on the right side of the qubit 110. Between the upward and downward stray magnetic field components is a horizontal component of the stray magnetic field acting in a direction opposite of B_{H}. This arrangement reduces the total magnetic field acting on the qubit 110, resulting in improved signal coherence.

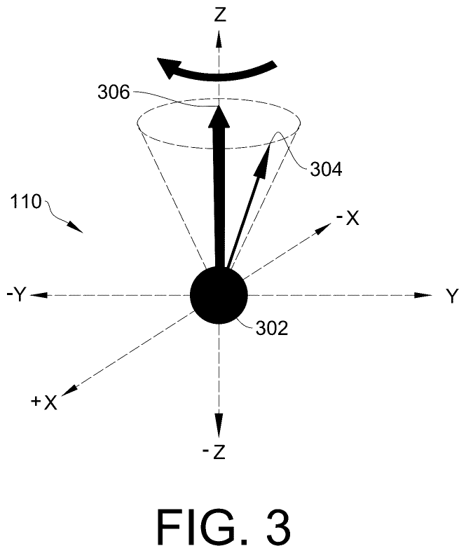

FIG. 3 illustrates one of the qubits 110 by its hole wavefunction 302 and its spin 304 precessing around a vertical external field B_{Z} in this example. The energy of the spin 302 can be computed in terms of its frequency:

$${hf}_{i} = {μ}_{B} gB \qquad ( Eq . 1 )$$

where h is the Planck's constant and μ_{B} the Bohr magneton, B is the total magnetic field vector:

$$B = ( \begin{matrix}{B}_{x} \\ {B}_{y} \\ {B}_{z}\end{matrix} ) \qquad ( Eq . 2 )$$

and g for hole spin qubits with strong spin-orbit interaction, such as in Ge/SiGe holes, can be a g-tensor:

$$g = ( \begin{matrix}{g}_{x} & & \\ & {g}_{y} & \\ & & {g}_{z}\end{matrix} ) \qquad ( Eq . 3 )$$

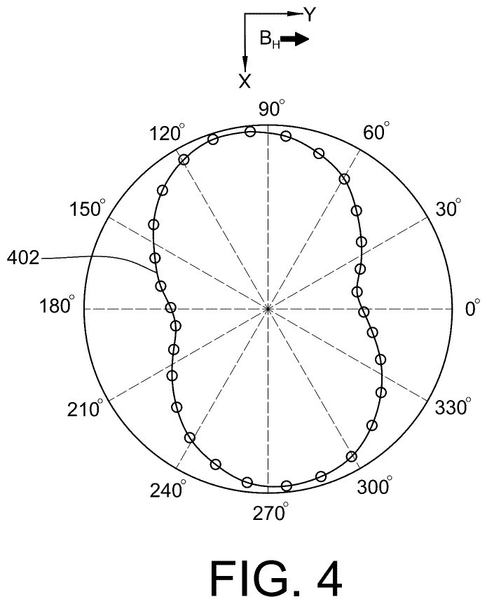

FIG. 4 plots a cross section 402 of the g-tensor as a function of the in-plane homogeneous field B_{H} that is within the xy coordinate plane in this example. We consider a g-tensor that is anisotropic, with larger values along the z-direction, and smaller values in the x-y plane. Such anisotropic g-tensors are typical for hole spin qubits where a strong quantization of the hole wavefunction along the z direction provides a large g_{z} component. For example, it may have its largest values near to 90 and 270 degrees, and smaller values near to 0 and 180 degrees. This characteristic can greatly amplify the out-of-plane (antiparallel) component of the magnetic stray-field B_{Z} as compared to the in-plane components Bₓ, B_{y}. Amplification in this context is realized by the much stronger effect of the out-of-plane component B_{z} on the Larmor precession frequency of the hole spin.

Returning to FIG. 3, the Larmor vector 306 defines the precession axis. The Larmor frequency is related to the total magnetic field by the g-tensor (Eq. 1). The g-tensor is a material characteristic of the qubit 110 and depends for example on the electric field environment of the hole spin. The g-tensor links the Larmor vector 306 to the total magnetic field. If the g-tensor is isotropic, then the Larmor vector is aligned to the total field. However, if the g-tensor is anisotropic, as for the hole spin qubits 110 in these illustrative embodiments, then the Larmor vector 206 and the magnetic field directions can be very different. Thus, a frequency of the hole spin qubits 110 depends on a direction of the total magnetic field. The length of the Larmor vector 306 depends linearly on the magnitude of the total magnetic field, and the angle between Larmor vector 306 and magnetic field direction.

The present embodiments establish different designs to create magnetic field gradients provided by magnetic structures, aimed at tuning the qubit by displacing it in the magnetic field. In this way, each qubit is locally tuned to orient its anisotropic g-tensor.

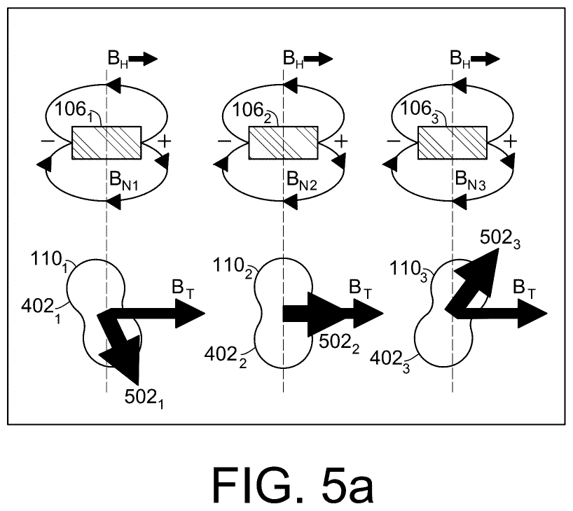

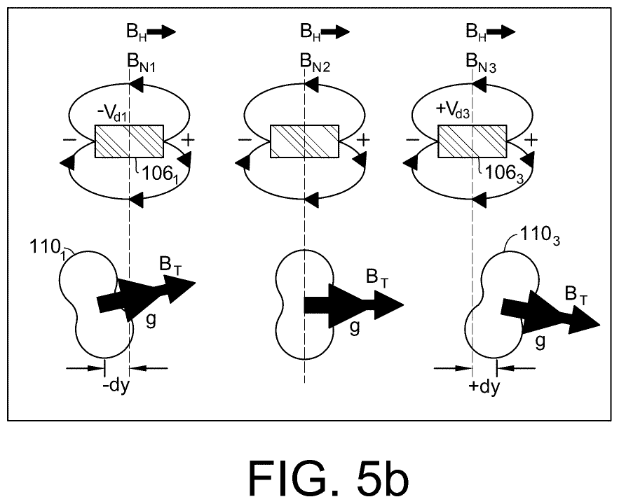

FIG. 5a illustrates the significance that the initial position has on the direction of the Larmor vector 502. The center qubit 1102 has an initial position where it is in perfect vertical alignment with B_{N2}, as in FIG. 2a. This would theoretically align the Larmor vector 502₂ to be parallel with the total magnetic field BT. Such an alignment of the Larmor vector 502₂ with the total magnetic field may improve (e.g., ideally optimize) signal fidelity of the quantum gate operations, such as by optimizing quantum gate time and coherence.

As discussed above, the vertical components of the stray magnetic field B_{N} acting on the qubit 110 can be tuned by displacing the qubit 110 away from its equilibrium position by application of a displacement voltage V_{d}. Tuning the Larmor vector direction can enhance the sensibility of the hole wavefunction to the driving voltage applied. Decoherence is related to a decoherence gradient, the gradient of the total field experienced by the qubit 110. As discussed above, the horizontal component of the stray magnetic field B_{N} acts opposite of B_{H}, thereby reducing the total magnetic field acting on the qubit 110. Since decoherence time depends on the total field acting on the qubit, having B_{N} antiparallel to B_{H} improves the qubit decoherence time by reducing the total field at the qubit location. Accordingly, the present embodiments are configured to enhance the quantum gate's 106 fidelity by enhancing the sensibility to the driving voltages while also decreasing the total field at the qubit position.

However, the initial positions are typically misaligned with B_{N1}, B_{N3}, as depicted by the outer qubits 110₁, 110₃. Qubit 110₁ has a precession axis tilted to the left, and qubit 110₃ has a precession axis tilted to the right. Small angular misalignments can result in significant Larmor vector tilt, shown by the Larmor vector 5021 oriented spin down at its initial position and the Larmor vector 5023 oriented spin up at its initial position.

So, without the individual qubit tuning of this disclosure, the signal fidelity of quantum gate operations generally depends on the orientation of the Larmor vector 502 at its initial position with respect to the direction of the total magnetic field and the electric fields used for qubit manipulation. The Larmor vector 502 orientations can vary among different qubits 110. This variation can be caused by strain, fabrication imperfections, misalignments, and the like. Slight misalignments can result in large Larmor vector tilting. A sign change for B_{z} can cause a Larmor vector tilt of ninety degrees and more.

There are two kinds of electric field variations, undesired variations (e.g. from charge fluctuations in the material) and desired variations (made by changing the voltage on nearby metallic gates). The undesired variations can modify the length of the Larmor vector, causing frequency fluctuation and leading to qubit dephasing. This must be avoided in order to improve coherence. The desired fluctuations are intended to generate single-qubit gates that control the direction of the Larmor vector. Both avoiding the undesired fluctuations and maximizing the directional change of the Larmor vector can be achieved by choosing a suitable direction of the total magnetic field. Such a direction is understood as a sweet spot where dephasing is minimized and single-qubit gate speed is maximized. As the g-tensors of individual qubits can differ, different local magnetic fields may need to be applied to each qubit to put each qubit in the sweet spot.

FIG. 5b is similar to FIG. 5a but after applying baseline displacement voltages-Val, +V_{d3} to the gates 106₁, 106₃ to spatially displace the qubits 110₁, 110₃. The negative baseline voltage-Van spatially displaces the qubit 110₁ relative to B_{N1} in a direction of the negative y-axis (−dy). This misalignment subjects the qubit 110₁ to upward vertical components of the stray magnetic field B_{N1}. The upward pointing component of B_{N1} increases proportionally to the displacement. A certain gate voltage (tuning voltage)−V_{dt} will displace the qubit 110₁ relative to B_{N1} enough to flip the Larmor vector 5021 state from pointing downwards (FIG. 5a) to pointing towards the same direction as the other Larmor vectors (FIG. 5b). This orients the Larmor vector 502₁ substantially parallel to a pre-determined direction set for all the qubits where signal fidelity of the gate 106₁ is optimized.

Similarly, the positive baseline voltage +V_{d3} spatially displaces the qubit 110₃ relative to B_{N3} in a direction of the positive y-axis (+dy). This misalignment subjects the qubit 110₃ to downward vertical components of the stray magnetic field B_{N3}. The downward vertical gradient from B_{N3} increases proportionally to the positive displacement. A certain gate voltage (tuning voltage) V_{d3} will displace the qubit 110₃ relative to B_{N3} enough to flip the Larmor vector 502₃ state from pointing upwards (FIG. 5a) to pointing towards the same direction as the other Larmor vectors (FIG. 5b). This orients the Larmor vector 502₃ substantially parallel to a predetermined direction set for all of the qubits where signal fidelity of the quantum gate 106₁ is optimized.

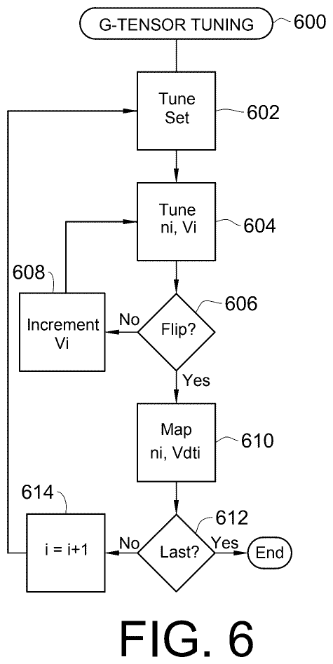

FIG. 6 is a flowchart depicting a method 600 for g-tensor tuning to optimize the signal fidelity of quantum gates in a qubit computing system, consistent with illustrative embodiments. The method 600 employs tuning values V_{dt} to individually tune each qubit in an array of qubits to the magnetic field. The method 600 can begin by responding to a computer request from block 602 to tune a set of one or more qubits. In one example, block 602 can control tuning multiple qubits simultaneously in parallel processing to increase data throughput. Block 604 can begin the tuning process for a first qubit nᵢ of the tune set. Block 604 can apply a baseline gate voltage Vᵢ to the qubit nᵢ. Block 606 determines whether the baseline gate voltage Vᵢ is sufficient to displace the qubit nᵢ relative to B_{N} enough to flip the spin state and orient the Larmor vector substantially parallel to the total magnetic field.

If the determination of block 606 is no, then block 608 can increment the baseline gate voltage and return control to block 604 to repeat the process for qubit nᵢ at the incremented gate voltage Vᵢ₊₁. This loop continues until an incremental gate voltage value displaces the qubit nᵢ relative to B_{N} enough to flip the spin state and orient the Larmor vector substantially parallel to the total magnetic field. The spin flipping incremental gate voltage value can define the tuning value V_{dti} for the individual qubit nᵢ. Block 610 can store the tuning value V_{dti} in a computer readable memory, such as by mapping qubit nᵢ to its tuning value V_{dti} in the computer readable memory. The tuning value V_{dti} can be recalled from the computer readable memory to optimize the signal fidelity of quantum gate operations during a subsequent manipulation of the qubit nᵢ. Block 612 determines whether the last qubit in the tune set has been tuned. If not, a counter 614 can be incremented and control can return to block 602 to repeat the method for the next qubit nᵢ₊₁ in the tune set until the computer request from block 602 is satisfied.

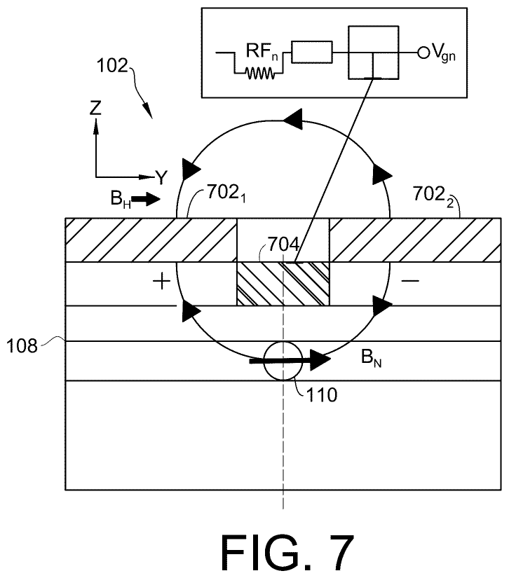

FIG. 7 depicts an alternative configuration of a two-piece magnetic structure 7021, 7022 overlying a gate 704. The two-piece magnetic structure 702 can be layered and etched on the semiconductor substrate 108. This configuration separates the quantum gate operations from the magnetic structure, allowing the gate 704 to be made of a nonmagnetic material. As before, the magnetic structure 702 is such that it is generally parallel to B_{H}. The qubit 110 can be individually tuned by applying the parametric tuning value V_{dt} to displace the qubit 110 relative to B_{N} sufficiently to orient the Larmor vector 302 substantially parallel to the total magnetic field BT.

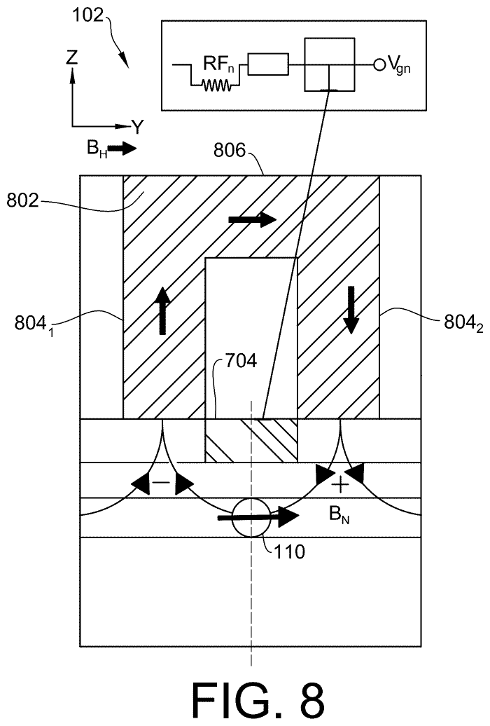

FIG. 8 depicts another alternative configuration of a horseshoe-shaped magnetic structure 802 overlying the nonmagnetic gate 704. The magnetic structure 802 can be layered and etched on the semiconductor substrate 108. In this way, the magnetic structure 802 can be about one micrometer long and can be located about 100 nanometers away from the qubit 110. As before, the magnetic structure 802 can be such that it is parallel to B_{H}.

The magnetic structure 802 has a pair of protuberant poles 804 extending orthogonally to the qubit 110 and its qubit plane. A joint 806 extends parallel to the qubit plane (and thus parallel to B_{H}) and joins the pair of protuberant poles 804 together. The elongated form of the protuberant poles 804 enhances the shape anisotropy contribution, forcing the magnetization to orient essentially along the structure, and enhancing the stray-field at the qubit 110 locations. The size of each magnetic structure 802 can be about one micrometer or smaller.

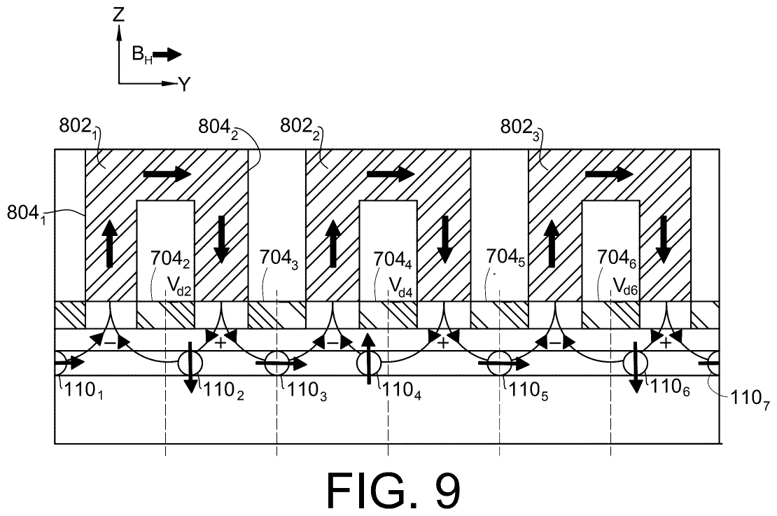

FIG. 9 depicts an elevational view of integrated circuitry architecture forming a one-dimensional array of qubits 110 with three horseshoe-shaped magnetic structures 802 in FIG. 8. Some of the qubits 110₂, 110₄, 110₆ are aligned between a pair of protuberant poles 804 in one of the magnetic structures 802. The other qubits 110₁, 110₃, 110₅, 110₇ are aligned between protuberant poles 804 of two adjacent magnetic structures 802. B_{N} can be a stray magnetic field extending between two of the protuberant poles 804, of the same or of two adjacent magnetic structures 802. Qubits 110₁, 110₃, 110₅, and 110₇ are depicted in their initial positions. Qubits 110₂, 110₆ are depicted in their displaced positions, as a result of applying displacement voltages.

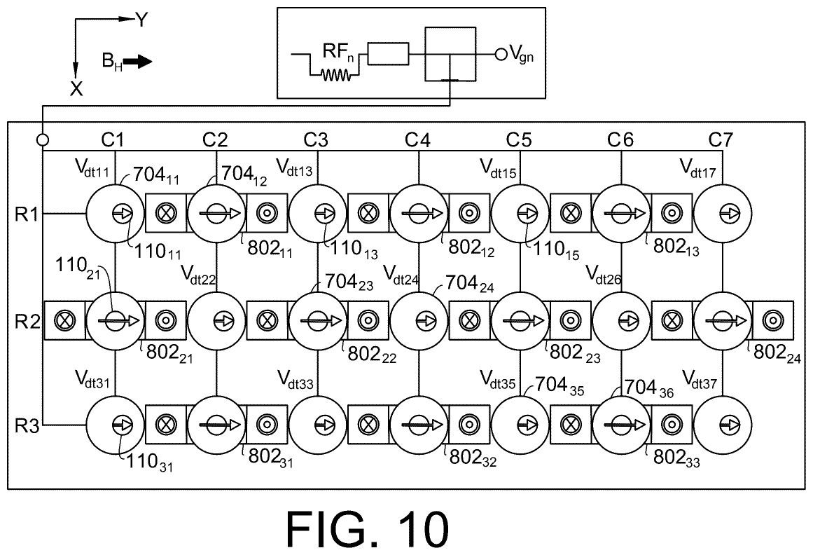

FIG. 10 depicts a bottom view of integrated circuitry architecture forming a two-dimensional array of qubits 110. A crossbar array is formed by a plurality of interconnecting rows and a plurality of columns. Each gate 704 is electrically connected at an intersection of a row control line Rm and a column control line Cn. Although FIG. 10 depicts each Rm and Cn as a single line for ease of illustration, one of skill in the art understands that each Rm and Cn can include multiple control lines interconnecting the gates 704. The tuning circuitry can likewise be interconnected to the gates 704 via the crossbar array. Other peripheral circuitries and data input/output circuitries can be interconnected with the gates 704 via the crossbar array for individually controlling each qubit 110 for such things as power, clock, bias, timing, and the like, to provide operable power distribution, control signals, clocking signals, and the like.

The top row R1 of this two-dimensional array includes seven qubits 110₁₁, 110₁₂, 110₁₃, 110₁₄, 110₁₅, 110₁₆, 110₁₇ in the same qubit plane. Four of those qubits 110₁₁, 110₁₃, 110₁₅, 110₁₇ are depicted being simultaneously tuned by application of respective parametric tuning voltages V_{dt11}, V_{dt13}, V_{dt15}, V_{dt17}. The middle row R2 is constructed similarly to R1 with seven qubits 110 in a second qubit plane. It depicts simultaneously tuning three qubits 110₂₂, 110₂₄, 110₂₆ by application of respective parametric tuning voltages V_{dt22}, V_{dt24}, V_{dt26}. The bottom row R3 is constructed and operated similarly to R1 with seven qubits in a third qubit plane. It depicts the simultaneous tuning of four qubits 110₃₁, 110₃₃, 110₃₅, 110₃₇ by application of parametric tuning voltages V_{dt31}, V_{dt33}, V_{dt35}, V_{dt37}.

The magnetic structures 802 are configured to individually tune each of one or more qubits 110. For example, magnetic structure 802₁₂ is configured to individually tune the qubits 110₁₃, 110₁₄, 110₁₅ in the first qubit plane. Similarly, magnetic structure 802₂₂ is configured to individually tune the qubits 110₂₃, 110₂₄, 110₂₅ in the second qubit plane.

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings. The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed:

1. An apparatus comprising:
a semiconductor substrate;
a plurality of quantum gates on the semiconductor substrate forming an array of hole spin quantum dots (qubits) at respective qubit positions in a qubit plane on the semiconductor substrate;
a magnetic field producing element configured to produce a total magnetic field, the magnetic field producing element comprising:
a homogeneous field producing element configured to produce a homogenous magnetic field acting collectively on all the qubits in the array in a direction parallel to the qubit plane; and
a nonhomogeneous field producing element configured to produce a nonhomogeneous magnetic field acting individually on each qubit in the array; and
tuning circuitry configured to optimize signal fidelity of the plurality of quantum gates by individually tuning each qubit to the total magnetic field.

2. The apparatus of claim 1, wherein each of the plurality of quantum gates comprises a magnetic structure that is parallel to the homogeneous magnetic field.

3. The apparatus of claim 2, wherein the magnetic structures comprise deposited and etched layers on the semiconductor substrate.

4. The apparatus of claim 2, wherein the nonhomogeneous field producing element comprises a plurality of stray field producing elements, each stray field producing element configured to produce a stray magnetic field extending from one end of each magnetic structure to an opposing end of each magnetic structure.

5. The apparatus of claim 4, wherein each stray field producing element subjects a corresponding qubit to:
a first stray magnetic field component in a direction of the homogeneous magnetic field; and
a second stray magnetic field component in a direction antiparallel to the homogeneous magnetic field.

6. The apparatus of claim 1, wherein the tuning circuitry is configured to define a tuning value for a selected qubit that substantially aligns a Larmor vector of the selected qubit along a predetermined direction.

7. The apparatus of claim 6, wherein the tuning value comprises a tuning voltage that displaces the selected qubit relative to the total magnetic field enough to align the Larmor vector with the predetermined direction.

8. The apparatus of claim 7, wherein the tuning value displaces the selected qubit from an initial position.

9. The apparatus of claim 2, wherein each magnetic structure comprises:
a pair of protuberant poles extending orthogonally to the qubit plane; and
a joint extending parallel to the qubit plane and joining the pair of protuberant poles together.

10. The apparatus of claim 9, wherein at least one of the qubits is aligned between one of the pair of protuberant poles in one of the magnetic structures.

11. The apparatus of claim 9, wherein at least one of the qubits is aligned between the protuberant poles of two adjacent magnetic structures.

12. The apparatus of claim 9, wherein the nonhomogeneous field producing element comprises a plurality of stray field producing elements, each stray field producing element extending between two of the protuberant poles.

13. The apparatus of claim 9 wherein the qubit plane is formed of a two-dimensional array of the qubits.

14. The apparatus of claim 13, further comprising:
a first magnetic structure configured to individually tune each of one or more of the qubits in a first row of the qubit plane to the total magnetic field; and
a second magnetic structure configured to individually tune each of one or more of the qubits in a second row of the qubit plane to the total magnetic field.

15. A method for g-tensor tuning to optimize signal fidelity of quantum gates in a qubit computing system, comprising:
applying a baseline voltage to a selected one of a plurality of quantum gates that each define an electrostatic potential of a quantum dot (qubit) in which a corresponding selected hole spin is confined; and
incrementing the baseline voltage by an additional voltage until reaching a tuning voltage that displaces the selected hole spin relative to a nonhomogeneous magnetic field producing element to orient a Larmor vector of the selected hole spin in a predetermined direction.

16. The method of claim 15, further comprising:
simultaneously applying a plurality of different baseline voltages to two or more of the plurality of quantum gates; and
incrementing each of the plurality of different baseline voltages until reaching respective tuning voltages displacing the qubits relative to the nonhomogeneous magnetic field producing element to orient the Larmor vectors of the qubits in predetermined directions.

17. The method of claim 16, further comprising mapping each individual qubit to its respective tuning voltage.

18. The method of claim 16, wherein the tuning voltages optimize quantum gate time and hole spin qubit coherence.

19. A quantum computing system configured to perform a method, comprising:
applying a baseline gate voltage to a quantum gate that forms a hole spin quantum dot (qubit); and
incrementing the baseline gate voltage until reaching a tuning voltage that displaces the qubit relative to a nonhomogeneous field producing element enough to orient a Larmor vector of the qubit in a predetermined direction.

20. The method of claim 19, further comprising:
simultaneously applying a plurality of different baseline voltages to two or more of a plurality of quantum gates that form qubits; and
incrementing each of the plurality of different baseline voltages until reaching respective tuning voltages displacing the qubits relative to the nonhomogeneous field producing element enough to orient the Larmor vectors of the qubits in predetermined directions.
